(19) United States
(12) Patent Application Publication
(10) Pub. No.: US 2003/0173948 A1
(43) Pub. Date: Sep. 18, 2003

(54) Measurement method and device, in particular for the high-frequency measurement of electric components

(76) Inventor: Georg Rudolf Sillner, Zeitlarn (DE)

Correspondence Address: HOFFMAN WASSON & GITLER, 2361 JEFFERSON DAVIS HIGHWAY, SUITE 522, ARLINGTON, VA, 22202

(21) Appl. No.: 10/276,337

(22) PCT Filed: May 22, 2001
(86) PCT No.: PCT/DE01/01949

(30) Foreign Application Priority Data
Jun. 2, 2000 (DE) 10027042.5
Apr. 19, 2001 (DE) 10119122.7

(51) Int. Cl. G01R 1/00

(52) U.S. Cl. 324/158.1

(57) ABSTRACT

The invention relates to a method and a device for measuring electric components, in particular for the high-frequency measurement of said components. The invention is characterized by the use of contact elements that can be displaced between an initial position and a measuring position. In the latter, the respective contact elements lie against a stop of the component and a measuring contact. Said contact elements are retained in supports including electrically insulated material.

### BACKGROUND OF THE INVENTION

The present invention relates to a process and device for high frequency measuring electrical components.

In the manufacture of small electric components, for example so-called “surface mounted devices” (SMDs), it is necessary that the components, or their electric values, be measured, or tested, in so-called “back-end machines”. For such components that are intended for use at high frequencies (GHz range), a special high-frequency measurement is required.

A measuring device (U.S. Pat. No. 4,047,780) is known in which the contact elements are provided on movable carriers and are formed by springs. For high-frequency measurements, and also for the measurement of components with very small dimensions, in which the connections are located very close together, this type of a device is not suitable.

A further measuring device (DE 196 10 462) is known in which the measuring contacts are formed by relatively long leaf-spring elements. Each connection of a component is allocated two such measuring contacts, which can be moved toward and away from the connection in the manner of tweezers. This known measuring device is not suitable for high-frequency measurements due to the long length of the measuring contacts. Furthermore, this known construction is problematic with respect to the arrangement of the measuring contacts when measuring components with very small dimensions.

Finally, a measuring device (IP 063 47 511) is known in which, for the simultaneous contact of several connections, measuring contacts are located on a strip-like contact carrier that can be moved perpendicular to its longitudinal extension to the contacts of the respective component in order to make the contact. The measuring contacts are connected with a measuring circuit via conductors. This known device is not suitable for high-frequency measurements.

The object of the present invention is to present a process and a measuring device that enables a reliable measurement together with high performance. The device has electrical connections extending from a component housing, whereby during measurement the connections of each component are connected with measuring contacts by means of movable contact elements. The contact elmeents slide or roll at least one measuring contact during movement from a starting position to a measuring position.

The present invention enables a reliable measurement, especially a high frequency measurement, together with high performance (measured components per time unit), by means of a particularly simple construction.

### BRIEF DESCRIPTION OF THE DRAWINGS

The invention is described in more detail based on a sample embodiment as depicted in the drawings, as follows:

FIG. 1 shows a simplified representation in top view of a component to be measured after being punched form the lead frame;

FIG. 2 shows a simplified representation in top view of a back-end machine for processing the components of FIG. 1;

FIG. 3 shows an enlarged partial representation of a measuring device according to the present invention;

FIG. 4 shows the measuring device of FIG. 1 in top view;

FIG. 5 and 6 show a partial representation in side view of the measuring device of FIG. 1 in two different working positions;

FIG. 7 shows an enlarged representation in top view of a component located in a receptacle or measuring position of the measuring device, together with the lateral measuring contacts;

FIG. 8 shows a simplified representation in side view of a measuring station with the measuring device of a facility for processing electric components, for example a back-end machine, for the electric components;

FIG. 9 shows an enlarged partial representation in side view of a further possible embodiment of a measuring device according to the present invention;

FIG. 10 shows a top view of the PCB or the contact element carrier of the measuring device of FIG. 9, together with a component located in the measuring position;

FIG. 11 shows a simplified representation in top view of the measuring device of FIG. 9; and

FIG. 12 shows an enlarged partial representation in side view of several disk-like contact element carriers of the measuring device of FIG. 9.

### DETAILED DESCRIPTION OF THE INVENTION

The drawings show electric components 1 in the form of SMDs with extremely small dimensions. The components 1 are intended for applications in the GHz range and have a 3 dB critical frequency of approximately 10 GHz. The components have a housing 2, in which the respective semiconductor chip is accommodated and on two opposite longitudinal sides of which the electric connections 3 are located on both sides of a middle plane M, i.e. in the depicted embodiment there is a total of six connections 3.

FIG. 2 shows for the purpose of illustration, a so-called back-end machine 4, which is used to punch out the individual components 1, which are arranged in a lead frame 5 in several parallel rows, from this lead frame in a punching station 6, to which the lead frame 5 is fed, and then to transport the components by means of a first transporter 7 to a second transporter 8, on which the components are held individually and in a pre-defined orientation, i.e. with their connections 3 perpendicular to the horizontal direction of transport A of the transporter 8 on the lower end of vacuum holders 9, which are arranged sequentially in the transport direction A of the transporter 8 and are moved in cycles. The components 1, which are for example, transistors or integrated circuits, etc. are moved by means of the transporter 8 to a measuring station 10, at which, in particular a high-frequency measurement or test of the high-frequency properties of each component 1 is conducted. Depending on the measuring result, among other things, the components 1 are then either sorted out or classified at stations 11 according to their properties, or sorted and placed in trays, or classified according to their properties at belt stations 12, or sorted and belted. Such a back-end machine, but not having a high-frequency measuring station, is described, for example, in the PCT application PCT/DE 98/00268 (WO 98/34452).

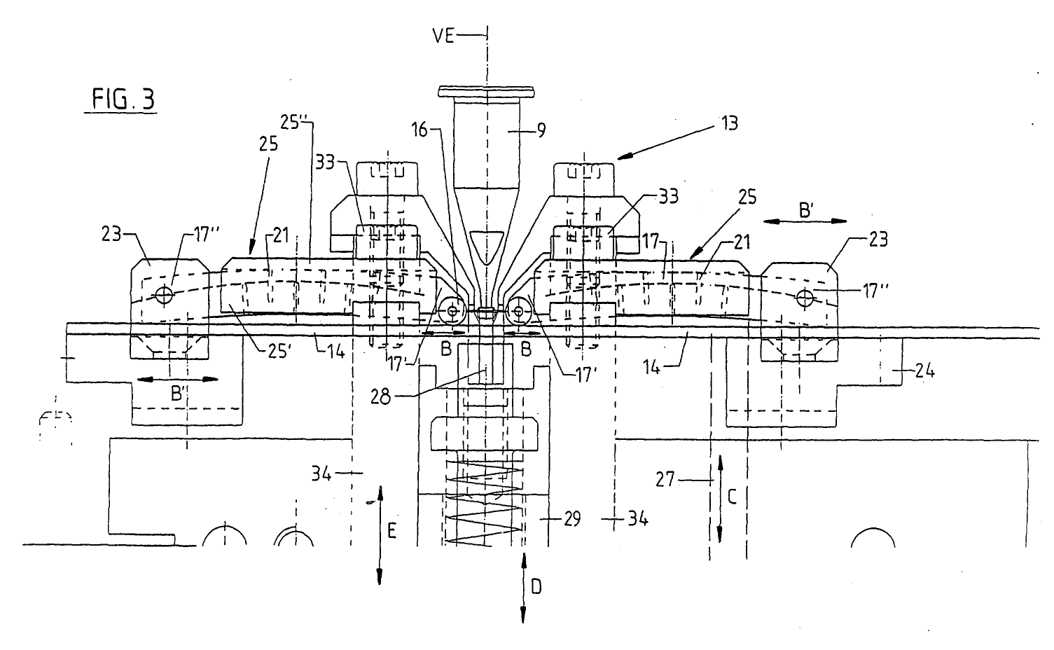

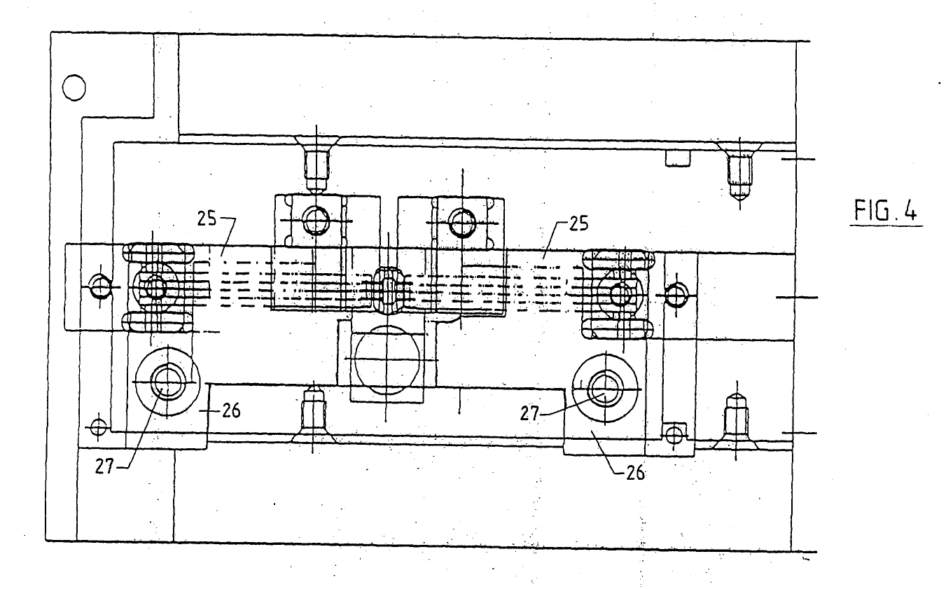

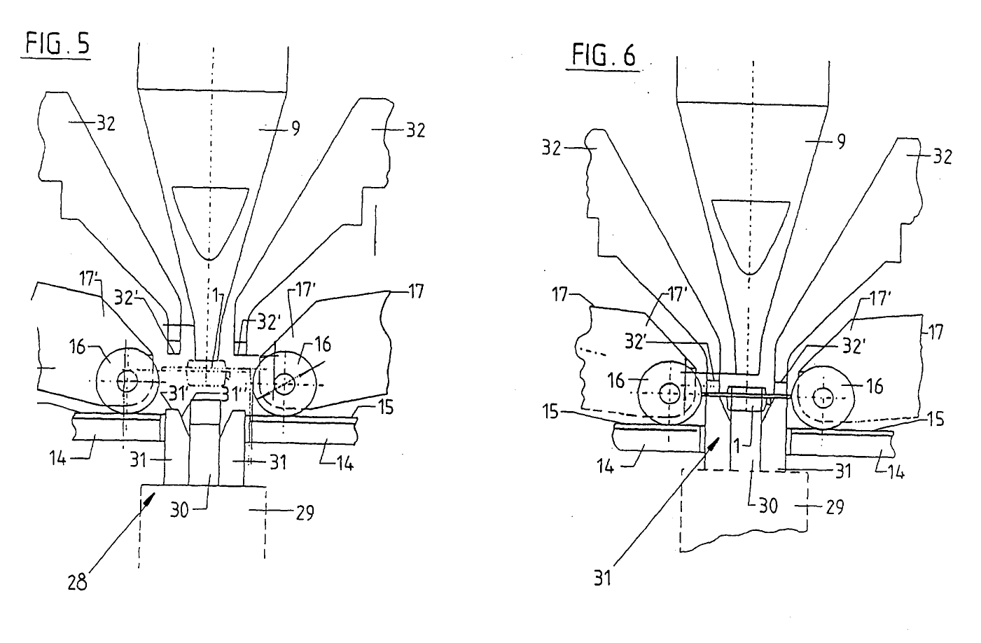

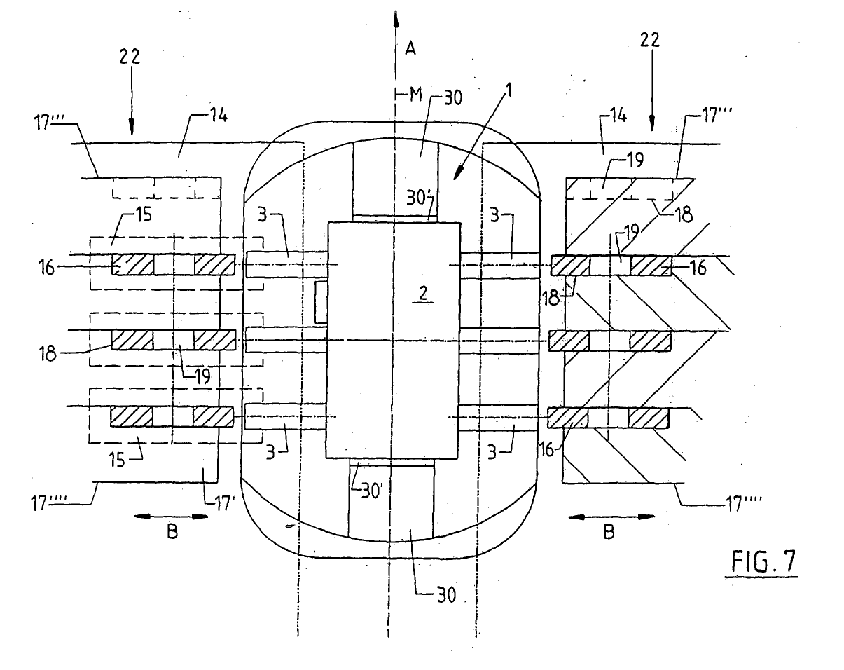

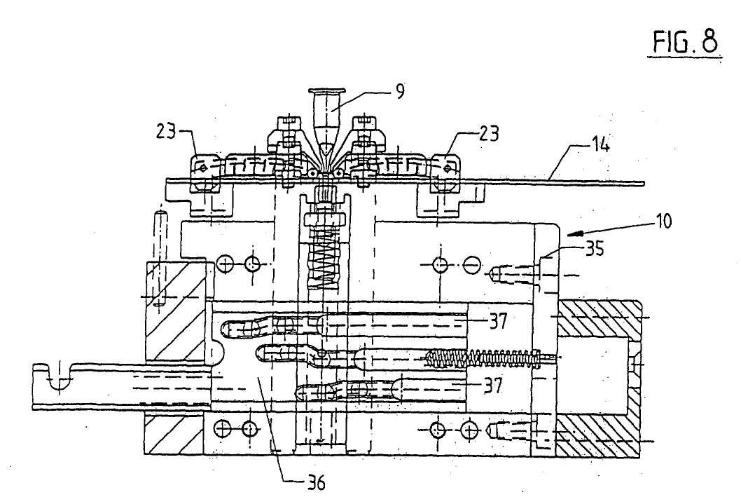

In order to achieve high performance for the back-end machine 4, it is also necessary that the high-frequency measurement of the individual components 1 is performed very quickly with the required high degree of precision. A measuring device that fulfills these conditions, among others, is described in more detail in FIGS. 3-7, where it is generally designated 13. FIG. 8 shows the measuring station 10 with the measuring device 13.

The measuring device 13 includes a printed circuit, board or substrate 14, which in the depicted embodiment, is oriented horizontally with its surfaces and is located beneath the movement path of the components 1 held on the vacuum holders 9.

The substrate 14, made of electrically flat insulating material, accommodates, among other elements, the electronic measuring circuitry and measuring contacts 15 on both sides of a vertical plane designated VE in FIGS. 3, 5-7. In the depicted embodiment, these measuring contacts are made of a rectangular, or stripe like, metal surface on the top of the substrate 14. The substrate 14 is, for example, a ceramic board, which, using for example the DCB process (direct copper bonding process—U.S. Pat, No. 3,744,120) known to experts and subsequent structuring and surface processing (nickel plating), is provided with the measuring contacts 15. In the depicted embodiment, the rectangular measuring contacts lie with their longitudinal side perpendicular to the plane VE enclosing the direction of transport A.

The number and arrangement of the measuring contacts 15 corresponds to the number and arrangement of the connections 3 of the components, in such a manner that whenever a component 1 has reached the measuring device 13, or the measuring position, located there during the pulsed movement of the transporter 8, each connection 3 of this component is located directly above a measuring contact 3. The middle plane M of the respective component 1 lies in the plane VE. The connections 3 extending on both sides from the component 1 lie with their longitudinal side perpendicular to the plane VE.

In order to create the shortest possible electrical connection path between the respective connection 3 and the corresponding measuring contact 15, the measuring device 13 is provided with movable contact elements 16, which in the depicted embodiment, are small rollers made of metal, i.e. of a metal that is suitable for measuring contacts. Due to the skin effect at high frequencies, the contact elements 16 can be made of copper, for example, with surface refinement (e.g. nickel plating).

The contact elements 16 can rotate freely on a horizontal axis parallel to the direction of transport A and can move in an axis direction perpendicular to the plane VE between a non-activated starting positions not contacting the connections 3 with a larger distance from the plane VE, and a measuring position, in such a manner that the contact elements 16 in the measuring position each contact the blunt end of a contact 3 with a precisely defined force, and likewise, with a precisely defined force contact the corresponding measuring contact 15 and therefore create the electrical connection between the respective connection 3 and the corresponding measuring contact 15 of the measuring circuit board 14, via two spatially separate contact areas.

During the movement from the starting position, into the measuring positions, and during the movement after measuring from the measuring position, back into the starting position, each of the contact elements 16 rolls off to its corresponding measuring contact 15, so that with each new measurement, each contact element 16 contacts the connection 3 and the measuring contact 15 with other surfaces, or contact areas, thus achieving a long useful life for the measuring device 13, and, in particulars its contact elements 16, preventing the need for replacement of this measuring device 13, or its contact elements 16, for example, due to contamination of the contact elements 16 with tin, which accumulates on the ends of the connections 3 during punching out of the components 1 from the tin-plated lead frame.

The described manner of producing the electric connection between the connections 3 and the measuring contacts 15, via the contact elements 16, has the advantage, for example, that the connection requires a very short path, which is essential for high-frequency measurement, and moreover that the contact on the connections 3 takes place on the front surfaces on the free ends of these connections, which (ends) were just produced by punching out the components 1 from the lead frame 5. The free ends of the connections 3 form high-quality contact surfaces, in particular not contaminated by oxides, etc., which enables a reliable measurement in a short time. Furthermore, the contact elements 16 can be pressed against the respective connection 3 and against the corresponding measuring contact 15 with a precisely defined force, in order to achieve a reliable contact and measurement.

In the depicted embodiment, the roller-like or disk-like contact elements 16 are located on the end 17′ of a disk-like carrier 17, which is made of a plastic material suitable for high-frequency applications and is oriented with its surfaces perpendicular to the plane VE. Between the two ends 17′, and 17′, the carriers 17 are curved convexly on their upper longitudinal side and curved concavely on their bottom longitudinal side.

For holding the respective contact element 16, the end 17′ of the carrier 17 is provided with a recess 18 on a surface 17″′ with a depth equal to, or greater than, the thickness of the respective disk-like contact element 16. In each recess 18, there is a pin 19 that lies with its axis perpendicular to the surfaces of the carrier 17, and on which, the respective measuring element 16 can rotate freely on bearings. Furthermore, as the drawings show, the carriers 17 are each curved in the shape of an arch between their two ends 17′ and 17″ and otherwise located above the substrate 14 in such a manner that the concave lower longitudinal side of each carrier 17 extending between the ends 17′ and 17″ faces the top of the substrate 14.

The carriers 17 are each provided with notches 21 that partially extend from the convex upper longitudinal side of these carriers and partially from the lower concave longitudinal side. Due to the notches 21 the carriers 17 are elastically deformable in the manner of a clip spring, for example, by pressing on the upper convex longitudinal side, from the unstrained condition with a smaller radius of curvature between the two ends 17′ and 17″ to a strained condition with a larger radius of curvature and therefore with a larger distance between these two ends 17′ and 17″.

The carriers 17 are arranged directly neighbored to each other in stacks 22 on both sides of the plane VE, in the direction of transport A following each other in such a manner that each surface 17″′ with a contact element 16 located in the recess 18 there lies adjacent to a surface 17″″ of a connecting carrier 17, so that the contact element 16 in each carrier 17 is secured against falling out by the adjacent carrier 17. In order to secure all contact elements 16 in this ways the stack 22 has an additional carrier 17 without contact elements 16.

The carriers 17 of each stack 22 are fastened to a common bearing 23, of a carrier 24, on the end 17″ at a distance from the plane VE, in such a manner as to enable the quick exchange of the carriers 17. The substrate 14 is also fastened to the carrier 24.

The carriers 17 of each stack 22 are held between the shanks 25′ of a pressure plate with a U-shaped profile that bears with a yoke section 25″ connecting the shanks 25′ against the concave upper longitudinal side of the carriers 17 of the respective stack 22. Each pressure plate 25 is connected by means of a side shackle 26 with a tappet 27 that can be moved up and down in a controlled manner, as indicated in FIG. 3 by the double arrow C, so that each downward stroke of the tappet 27 above the pressure plates 25 results in a deformation of the carriers 17 in such a manner that the contact elements 16 move from the starting position to the measuring position, in which they bear against the respective connection 3 and the contact surface 15 with the defined force. With the upward stroke of the tappet 27 the contact elements 16 move back to their starting position (double arrow B).

Furthermore, on the measuring device 13, or the measuring position there, there is a lower centering and clamping unit 28 that is spring-mounted on the upper end of a vertical tappet 29, which can move vertically upwards and downwards by a specified stroke (double arrow D) by means of the driving mechanism of the measuring station 10 accommodating the measuring device.

The centering and clamping unit 28 forms an open V-shaped receptacle 30 toward the top with two lateral angled centering surfaces 30′, which are offset from each other in the direction of transport A and against which, for the purpose of centering, the front sides of the components 1, or their housings 2 that do not have the connections 3 bear. Furthermore, the centering and clamping unit forms two lower clamping elements 31, which are offset in relation to the centering surfaces 30′ by 90° on the vertical axis and form clamping surfaces 31″ on their free ends and angled centering surfaces 31″ connecting to the latter, for centering of the component 1 or its housing 2 on the longitudinal sides possessing the connections 3. The centering surfaces 31″ have, for example, a rib-like design so that they work together with the longitudinal sides of the housings 2 possessing the connections 3 only outside of these connections 3.

The centering and clamping unit 28, or its centering element 30, with the centering surfaces 30′ and their clamping elements 31 are, for example, a single functional element. However, it is also generally possible to design the centering and clamping unit 28 of several parts, in particular, in such a manner that a relative vertical movement between the centering unit 30 and the clamping elements 31 is possible

On the measuring device 13, there are two upper clamping elements 32, on both sides of the plane VE, such that each upper clamping element 32 lies opposite a clamping surface 31, with a clamping surface 32′.

The elements of the centering and clamping unit 28, and the upper clamping elements 32, include an electrically insulating material that is suitable for high-frequency applications and is non-wearing, and are made of ceramic, for example, at least in their areas that lie adjacent to the respective component 1 to be measured. The upper clamping elements 32 are fastened to a holder 33, which in turn is held on the upper end of a vertical tappet 34, which can move upwards and downwards by a predefined stroke (double arrow E) by means of a driving mechanism.

The function of the measuring device 13 can therefore be described as follows:

Whenever a component 1 held on a vacuum holder 9 has reached the measuring position of the measuring device 13, the following functions are carried out during the following stopped phase of the pulsed transporter 8:

First, the centering and clamping unit 28 is moved upward by means of the tappet 29, so that the component 1 is received by the centering hole 30, is centered there on the centering surfaces 30′ in the axis of the direction of transport A, with the component 1 being held by the vacuum holder 9. The clamping surfaces 31′ bear against the bottom side of all connections 3. The connections 3 lie in a common plane perpendicular to the plane VE above the plane in which the axes of the disk-like contact elements 16 are located.

The upper clamping elements 32 are then lowered by the synchronous actuation of the corresponding tappet 34, whereby the connections 3 are first clamped between the clamping surfaces 31′ and 32′ and during the further downward movement of the clamping elements 32 and the elastic deformation of the centering and clamping unit 28 the respective component 1 is released from the vacuum holder 9, now in the position secured between the clamping elements 32 and the centering and clamping unit 28. The component 1 is lowered so far that the plane of the connections 3 is in the plane in which the axes of all contact elements 16 are located.

Once this state is achieved, the carriers 17 are deformed by synchronous actuation of the tappet 27 and by lowering of the pressure plates 25 in such a way that the disk-like contact elements 16 are pressed with a pre-defined force against the ends of the connections 3 extending only partially from the lower clamping elements 31 and the upper clamping elements 32 and simultaneously also with a pre-defined force against the corresponding measuring contact 15.

The forces with which each contact element 16 is pressed against the connection 3 and against the measuring contact 15 are determined, with a pre-defined stroke of the pressure plate 25, by the elasticity or spring constant of the carriers 17 and their curvature.

After conducting the measurement, the described functional elements are moved in the reverse order, i.e. first the pressure plates 25 are moved upward in order to release the connections 3 by the measuring elements 16. Afterwards, the clamping elements 32 are moved upward, so that with a following spring-mounted centering and clamping unit 28 and the resulting still securely held component 1, this component is again held with its housing 2 by the vacuum holder 9. After the final upward movement of the clamping elements 32 and after lowering of the centering and clamping unit 28 the measured component is then further transported in the new movement step of the transporter 8 and a new component 1 arrives at the measuring position of the measuring device 13.

The fact that there is a space between the respective component 1 and the vacuum holder 9 during the measurement insures, for example, that the measurement is not falsified by the vacuum holder 9, especially if this vacuum holder is made of a material that is not suitable for high-frequency applications and/or if foreign matter etc. that could negatively affect the high-frequency measurement has accumulated in the vacuum holder 9.

The measuring device 13, as described above, is part of a measuring station 10 and is located there on the top of a housing 35 of this measuring station. In the housing 35 there is a central slide 36, in an axis direction perpendicular to the plane VE. The slide 36 has several regulating grooves 37, into which the drivers or guide elements located on the tappets 27, 29 and 34 are inserted. The regulating grooves 37 are designed in such a way as to guarantee that the movements of the functional elements of the measuring device 13 or of the measuring station 10 are carried out in the required sequence. The slide 36 is controlled by the central driving mechanism of the back-end machine. The measuring station 10 can be replaced as an integral unit.

As described above, the measurement of the component 1 takes place in the depicted embodiment before bending of the connections 3 into the S-shape that is usual for SMD components.

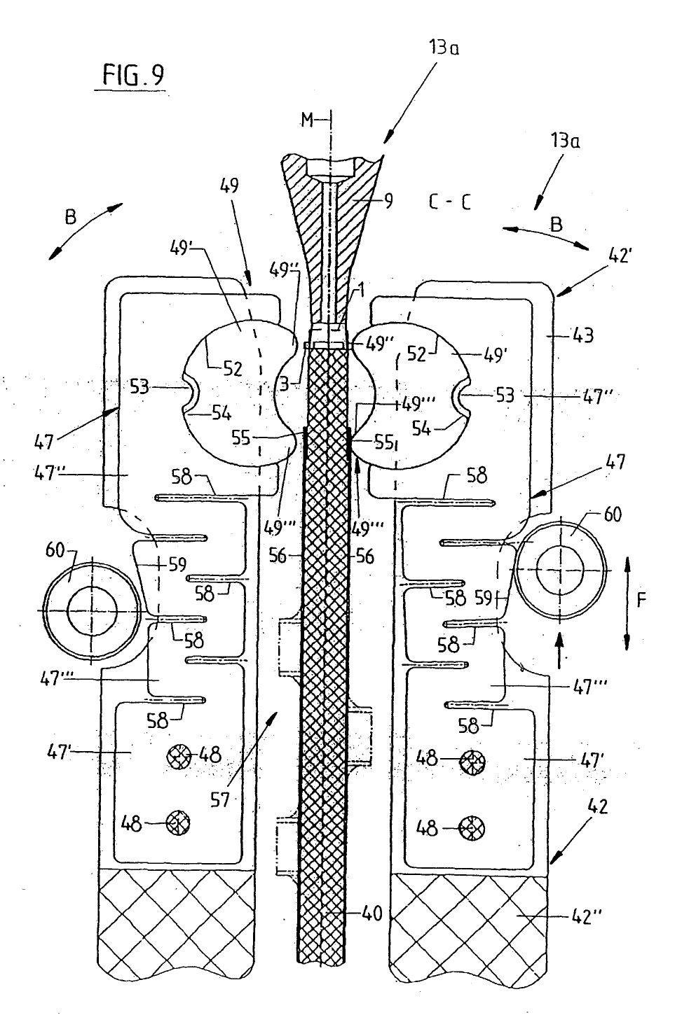

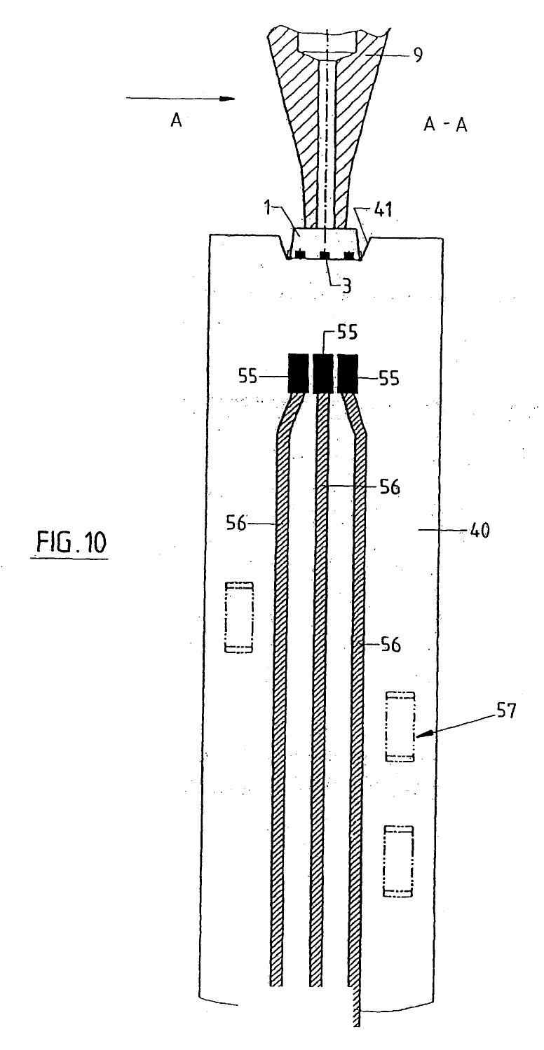

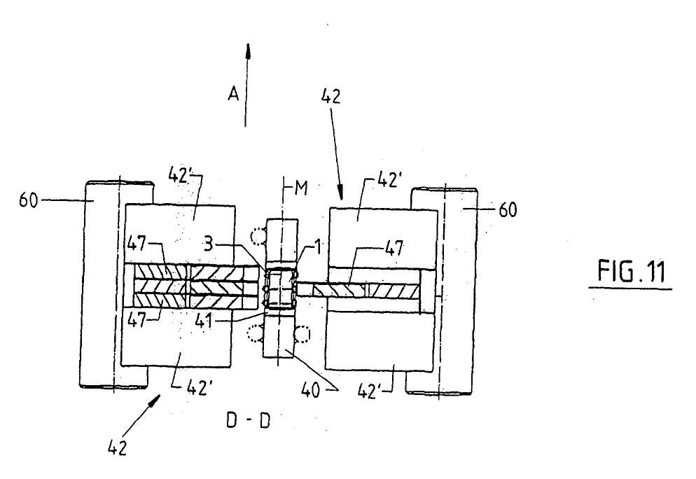

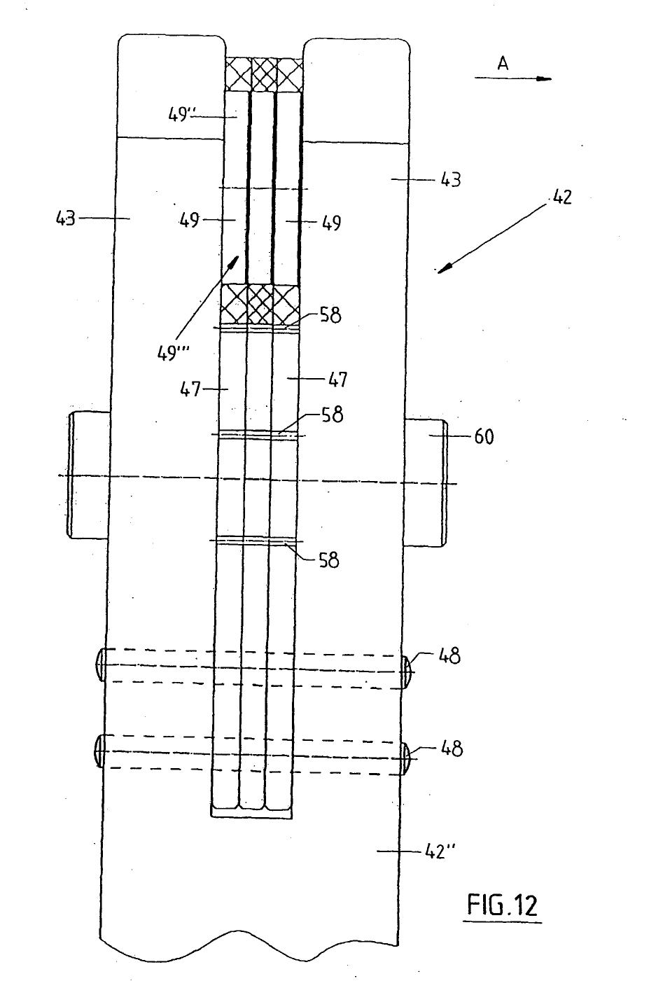

FIGS. 9-12 show, as a further possible embodiment of the invention, a measuring device 13a. This includes, among other elements, of a PCB or substrate 40, which is made of a flat insolating material and the surfaces of which are oriented in vertical planes, parallel to the horizontal direction of transport A of the transporter 8, of which only the vacuum holders 9 are depicted in FIGS. 9-12. The direction of transport A runs perpendicular to the drawing plane of the representation selected for FIG. 9.

The top of the substrate 40 forms a receptacle 41 that defines the measuring position and into which the respective component 1 can be inserted by means of the vacuum holder 9 in such a manner that the component 1 in the receptacle 41 corresponds exactly to a pre-defined orientation and is arranged perpendicular to the horizontal direction of transport A on both sides of a middle plane M enclosing this direction of transport and extending parallel to the surfaces of the substrate 40. On both sides of the substrate 40, there are two holders 42 made of an electrically insulating material, for example of plastic, which have a fork-shaped design in their upper area at 42′, both with two parallel fork arms 43 that are at a distance from each other in the direction of transport A and that extend vertically upward starting from their lower area 42″. On the lower area 42″ each holder 42 is solid, i.e. not fork-shaped and is held on a machine frame that supports the substrate 40.

Between the two fork arms 43 of each holder 42, there are several carriers 47 corresponding to the carrier 17, which are made of an electrically non-conductive material, preferably of plastic, likewise sheet or plate-shaped in such a manner that the larger surfaces of these carriers 47 are oriented in vertical planes perpendicular to the direction of transport A. In the depicted embodiment, there are three carriers 47 directly neighbored to each other in the manner of a plate packet on each holder 42 between the two arms 43. Each carrier is secured on its lower end 47′ in FIG. 9 against rotating on the corresponding holder 42, but can be easily replaced, using two pins 48, the axes of which are parallel to the direction of transport A and which are provided collectively for all carriers 47 of a holder 42 and which extend through congruent holes in the carriers 47 and in the arms 43 of the respective holder 42. On the upper free end 47″, contact elements 49 are held in some carriers 47, in such a manner that these contact elements 49 can pivot by a defined angle on an axis parallel to the direction of transport A.

The contact elements 49 in the depicted embodiment are designed with at least two layers. They include of the layer 50 made of an electrically insulating material. This layer forms one surface of each contact element 49, such that the layer 50 separates and electrically insulates the adjacent contact elements 49. Furthermore, each contact element 49 includes a layer 51 made of an electrically conductive material, for example of copper. The free surfaces of this layer 51 are provided with an electrically conductive surface made of an anti-corrosive and mechanically stable metal, such as nickel. The layer 51 forms the other respective surface of the plate or disk-shaped contact elements 49. In the depicted embodiment, the thickness of the layer 50 is considerably smaller than the thickness of the layer 51. In certain cases, especially also for reducing capacitive influences between adjacent contact elements 49 during high-frequency measurements it may be useful or necessary to increase the distance between the adjacent layers 51 by selecting a thickness of the respective layer 50 that is considerably larger than the thickness of the layer 51.

As FIG. 9 further shows, each contact element 49 is shaped so that it is part of a circular disk in a sub-section 49′. This sub-section 49′ is used to accept each contact element 49 in a graduated circular recess 52 of the respective carrier 47, in such a manner that the recess 52, in relation to its imaginary center, encloses the sub-section 49′ for a length larger than 180°, but smaller than 270°. In this way, each contact element 49 is held in the recess 52 of the corresponding carrier 47, but at the same time can pivot on the horizontal axis extending through the imaginary center of the recess 42 and parallel to the direction of transport A. In order to limit the pivot movement, a projection 53 is provided in each recess 52 that engages in a recess 54 of the respective contact element 49. The width of the recess 54 is larger than the corresponding width of the projection 54, corresponding to the possible pivot angle of the contact element 49.

The recess 52 of each carrier 47 is open on both surfaces of this carrier and also on the side of the carrier 47 facing the substrate 40, so that each contact element 49 extends from the recess 52 on this open side, with two sub-sections 49″ and 49″′, of which the sub-section 49″ during the measurement of the component 1 forms the contact area working together with the respective connection 3 of the component and the sub-section 49″′ forms the contact area that bears against the respective measuring contact 55 on the substrate 40 during the measurement. On the sub-sections the conductive layer 51 extends somewhat beyond the layer 50.

The measuring contacts 55, which are located on both surfaces of the substrate 40, are connected with the electronic measuring circuitry 57 by means of circuit board conductors 56, which are likewise located on the substrate 40 in the direct vicinity of the measuring area formed by the contact elements 49, between the substrate 40 and the carriers 47 with the contact elements 49 located on both sides of this substrate. This ensures short electrical paths, which enables a high-frequency measurement of the components 1.

Furthermore, as shown in particular in FIG. 9, each carrier 47 is provided with a plurality of notches 58 in its area 47″′ between the two ends 47′ and 47″, which (notches) are positioned horizontally with their longitudinal sides in such a way that the carriers 47 in the section 47″′ have a meandering course, which causes the disk-shaped carriers 47 to have an elastic design despite their perpendicular orientation to the direction of transport A, such that the free ends 47′ in the plane of their surfaces can be pivoted elastically on an imaginary axis parallel to the direction of transport A from a starting position, in which the respective contact element 49 is at a distance both from the connection 3 of a component 1 inserted into the receptacle 41 and from the measuring contact 55, into a measuring position (double arrow B), in which the sub-sections 49″ or 49″′ bear against a connection 3 or against a measuring contact 55, thus establishing an electric connection between a connection 3 of the component 1 and a measuring contact 55.

In order for the carriers 47, or their contact elements 49, to pivot from the starting position into the measuring position, the carriers 47 each form an angled or control surface 49 in their middle section 47″′ on the outer edge facing away from the substrate 40 in such a manner that the distance of this angled surface 49 from the middle plane M increases toward the free end 47″. This (control surface) is formed on each carrier 47 between two notches 58. Rollers 60 act on the control surfaces 49 and can be moved by a pre-defined stroke vertically upwards and downwards parallel to the middle plane M (corresponding to the double arrow F) by a driving mechanism of a machine accommodating the measuring device 13a, e.g. a back-end machine. With each upward movement of the rollers 60, the corresponding carriers 47 or their contact elements 49 are pivoted from the starting position into the measuring position, against the inherent elasticity of the carriers 47.

Since the control surfaces 49 are located between two notches 58 that are open toward the control surface 49 and an additional notch 48 is provided opposite of each control surface 49, the individual contact elements 49 can bear elastically against the respective connection 3 and the corresponding contact surface 55, so that a reliable contact of all contact elements is ensured even in case of tolerances for example in the connections 3 of the components 1.

The function of the measuring device 13a can be described as follows:

Whenever a component 1 held on a vacuum holder 9 has reached the measuring position of the measuring device 13a formed by the receptacle 41, the following functions are carried out during the subsequent stopped phase of the pulsed transporter 8:

First, the component 1 held on the vacuum holder 9 is inserted into the receptacle 41 by lowering the vacuum holder 9, which causes it to be centered. The component 1 is then held between the bottom of the receptacle 41 and the respective vacuum holder 9 by clamping.

Afterwards, the contact elements 49 are pivoted by an upward movement of the rollers 60 from the starting position into the measuring position, in which these contact elements create the electrical connection between a connection 3 and a measuring contact 55, so that the measurement can be conducted.

The relatively solid design of the contact elements 49 prevents negative influences on the high-frequency measurement, such as skin effect, partial inductivities, etc.

The above description assumed that one contact element 49, which works together with a measuring contact 55, is provided for each connection 3. However, a preferable embodiment could also provide for two contact elements 49 for each connection 3, preferably with a separate carrier 47 for each contact element. Each contact element 49 is then allocated a separate measuring contact 55 on the substrate 40, so that the electronic measuring circuitry 47, by means of a contact element 49 allocated to a connection 3, can also determine the contact or transition resistance for the respective connection 3, enabling for example the automatic calibration of the measurement.

The invention was described above based on a sample embodiment. Of course, numerous modifications and variations are possible without abandoning the basic inventive idea of the invention.

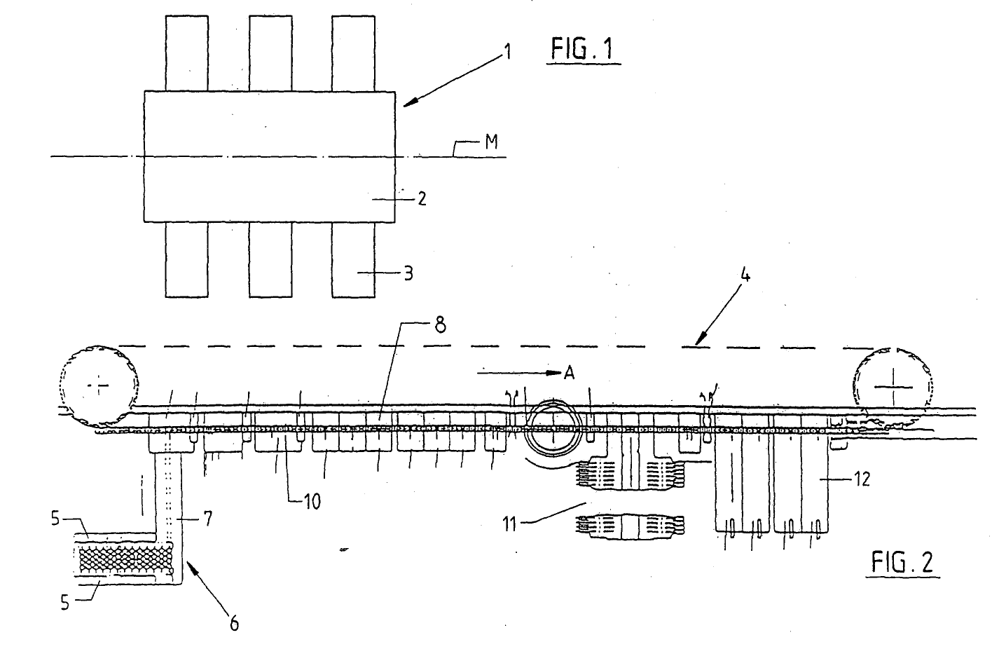

For example, it was assumed above in connection with FIGS. 1-8 that the individual carriers 17 are actuated by a pressure plate 25 acting on the surface of these carriers between the ends 17′ and 17″ in order to move the contact elements 16 forward and backward. Generally, it is also possible to move the contact elements 16 forward and backward by having the carriers 17, the top side of which bears against a fixed stop, e.g. against a non-movable pressure plate, move forward and backward at their ends 17″ in the direction of the plane VE, as indicated in FIG. 3 by the double arrow B′, by means of corresponding controlled movements of the bearing 23. Of course, it is also possible to combine the two drive types.

In place of the disk-shaped contact elements 16 other contact elements are conceivable, such as contact elements that slide on the measuring contacts 15, for example.

### Reference Number List

1 component

2 component housing

3 connection

4 back-end machine

5 lead frame

6 punching station

7, 8 transporter

9 vacuum holder

10 measuring station

11 sorting station

12 belt station

13, 13a measuring device

14 substrate with measuring contacts of the measuring circuit

15 measuring contact

16 movable contact element

17 contact element carrier

17′, 17″ end

17″′, 17″″ surface

18 recess

19 pin

21 notch

22 stack

23 bearing

24 carrier

25 pressure plate

25′ shank

25″ yoke element

26 extension (shackle)

27 tappet

28 centering and clamping unit

29 tappet

30 centering element

30′ centering surface

31 clamping element

31′ clamping surface

31″ centering surface

32 clamping element

32′ clamping surface

33 holder

34 tappet

35 housing

36 regulating slide

37 regulating groove

40 substrate with measuring contacts of the measuring circuit

41 retainer

42 holder

42′, 42″ section

43 fork arm

47 carrier

47′, 47″, 47″′ section

48 pin

49 contact element

49′, 49″, 49″′ sub-section

50, 51 layer

52 recess

53 projection

54 recess

55 measuring contact

56 circuit board conductor

57 electronic measuring component

58 notch

59 angled or control surface

60 roll

A direction of transport

B, C, D, E, F direction of movement or swiveling

M middle plane

VE vertical plane

What is claimed is:

1. A process for high-frequency measuring of electrical components, the components have electrical connections extending from a component housing, whereby during a measurement the connections of each component are connected with at least one measuring contact of a measuring circuit by means of movable contact elements, wherein the movable contact elements slide or roll on at least one measuring contact of the measuring circuit during movement from a starting position to a measuring position.

2. The process as claimed in claim 1, wherein the connections are made of material sections of a lead frame remaining on the electrical component during punching out of the components from the lead frame, and that during the measurement the electrical connection between the contact elements and the electrical connection takes place on a cut side or a face of the contacts created during punching.

3. The process as claimed in claim 1, wherein the contact elements during the measurement, contact the at least one measuring contact with a first surface or a first contact area and the connection of the component with a second surface or a second contact area at a distance from the first contact.

4. The process as claimed in claim 2, wherein the measurement takes place in a production line directly after the punching out of the components from a lead frame.

5. The process as claimed in claim 1, wherein the connections are secured against lateral yielding or bending during the measurement.

6. The process as claimed in claim 5, wherein the connections are clamped between clamping elements during the measurement.

7. The process as claimed in claim 6, wherein clamping elements are used that comprise an electrically insulating material at least on the clamping surfaces the mateirial is comprised of a ceramic that displays low dielectric losses even at high frequencies.

8. The process as claimed in claim 1, wherein the components for measuring are guided on vacuum holders of a measuring device.

9. The process as claimed in claim 8, wherein the components at the measuring device before the measurement are removed from the holder while maintaining a predefined orientation and after the measurement are returned to the holder while maintaining a predefined orientation.

10. The process as claimed in claim 1, wherein the components are aligned before measuring.

11. The process as claimed in claim 1, wherein the contact element during the measurement contacts the measuring contact with a first, predefined force and contacts the connection with a second, predefined force.

12. The process as claimed in claim 11, wherein a first force is exerted in the direction perpendicular to the measuring contact and the second force is exerted in the longitudinal direction of the connection.

13. The process as claimed in claim 1, wherein the two contact areas, one of which is formed between the connection of the electrical component and the contact element and the other of which is formed between the contact element and the measuring contact, are located in an offset arrangement in an angled area on the outer surface of the contact element.

14. The process as claimed in claim 1, wherein the use of contact elements, which are located on a carrier made of an electrically insulating material.

15. The process as claimed in claim 14, wherein the movement of the contact elements takes place by moving the carriers.

16. The process as claimed in claim 14, wherein the movement of the contact elements takes place by deformation of the carriers, the carriers being clip springs.

17. A device for high-frequency measuring of electrical components the components comprise several electrical connections extending from a component housing, with a measuring circuit accommodating several measuring contacts and with contact elements, which can be moved for producing electrical connections between the electrical connections of the component to be measured and the measuring contacts from a starting position to a measuring position, in which the contact elements contact a connection of the component with a first contact area and contact a measuring contact with a second contact area, wherein the contact elements are each located on their own carrier, which comprise at least partially of an electrically insulating material, and which can be moved between a starting position and a measuring position with this carrier.

18. The measuring device as claimed in claim 17, wherein the carriers are clip springs.

19. The measuring device as claimed in claim 17, wherein for measuring components with at least two connections extending on at least one side of the housing there are at least two sheet or plate-like carriers adjacent to each other in a stack, each carrier with at least one contact element.

20. The measuring device as claimed in claim 17, wherein the carriers have a sheet or plate-shaped design and are arranged with larger surfaces perpendicular to an axis direction in which the connections follow each other along the at least one housing side of the component to be measured.

21. The measuring device as claimed in claim 17, wherein the carriers have a sheet or plate-shaped design, and the contact elements can be moved in an axis direction in the plane of the surfaces of the disk-shaped carriers between the starting position and the measuring position.

22. The measuring device as claimed in claim 17, wherein the carriers are held in a manner allowing them to be replaced, at one end at a distance from the contact elements on a bearing of the measuring device.

23. The measuring device as claimed in claim 18, further comprising means to elastically deform the clip-spring carriers in a form of enlarging a radius of curvature in order to move the contact elements from the starting position into the measuring position, the means to elastically deform and a pressure element acting on one convex side of the carriers.

24. The measuring device as claimed in claim 17, wherein the carriers at one end at a distance from the contact elements work together with a driving mechanism moving the carriers in their longitudinal direction, in order to move the contact elements between the starting position and the measuring position.

25. The measuring device as claimed in claim 17, further comprising means provided on a measuring position formed by the measuring device for centering and/or clamping the component to be measured and/or the connections.

26. The measuring device as claimed in claim 17, wherein the contact elements are provided on one first surface of the carrier and the carriers are arranged in a stack in such a way that each contact element on a first surface of a carrier is adjacent to a first surface of a carrier of the second surface of an adjacent carrier not possessing such a contact element.

27. The measuring device as claimed in claim 17, wherein the contact elements on the carrier are electrically conductive and are replaceable bodies at least on their outer surface.

28. The measuring device as claimed in claim 17, wherein the contact elements a disk- or roller-like design and can freely rotate or swivel on bearings on the carrier.

29. The measuring device as claimed in claim 17, wherein the contact elements have a disk- or roller-like design and can rotate freely on bearings on the respective carrier in such a way that the contact elements when moving roll between the starting position and the measuring position on the corresponding measuring contact.

30. The measuring device as claimed in claim 17, wherein the measuring position of the measuring device is such that each connection is at a distance in relation to at least one corresponding measuring contact in an axis perpendicular or approximately perpendicular to the surface of the measuring contact.

31. The measuring device as claimed in claim 18, wherein the curved clip-spring carriers face a plane with a concave side of their bend in which the measuring contacts are located.

32. The measuring device as claimed in claim 17, wherein means are provided to remove the component transported to the measuring device by means of a vacuum holder, from the vacuum holder before the measurement while maintaining a pre-defined orientation and to move the component to the measuring position and return it to the vacuum holder after the measurement.

33. The measuring device as claimed in claim 17, wherein the carriers each have a pin molded onto a rotatable bearing of a disk- or roller-like contact element.

34. The measuring device as claimed claim 17, wherein the movement of the contact elements and the movement of the centering and clamping means takes place by means of a common driving mechanism via regulating grooves, whereby the common driving mechanism comprises at least one regulating slide in a housing that accommodates the measuring device.

35. The measuring device as claimed in claim 17, wherein the carriers can be swiveled in a spring-like manner with their free end that accommodates the respective contact element from a starting position into a measuring position, whereby the carriers have a disk-like design and are swiveled elastically or in a spring-like manner in a plane of their larger surfaces.

36. The measuring device as claimed in claim 17, wherein the contact elements form two contact areas, which are spatially separate from each other and of which one contact area contacts one connection of the component and another contact area contacts at least one measuring contact during the measurement.

37. The measuring device as claimed in claim 17, wherein the contact elements with a disk-like sub-section can rotate or swivel in a graduated circular recess, for example, of the respective carrier, on an axis parallel to the movement of the contact element from the starting position into the measuring position.

38. The measuring device as claimed in claim 17, wherein the carriers each form a control surface, which works together with an actuating element to move the contact elements from the starting position into the measuring position, whereby the control surface is located on a section of the carrier that is located between the sub-section carrying the contact element and a further sub-section on which the carrier is held in a holder.

39. The measuring device as claimed in claim 17, wherein the respective contact element comprises at least two layers, of which one layer is made of an electrically insulating material and one layer is made of an electrically conductive material.

40. The measuring device as claimed in claim 17, wherein a separate carrier is provided for each contact element.

41. The measuring device as claimed in claim 17, wherein the device is part of a measuring station in a production line or machine that processes the electric components.
